(19) United States
(12) Patent Application Publication
(10) Pub. No.: US 2021/0057843 A1
(43) Pub. Date: Feb. 25, 2021

(54) Quick Exchange Docking Connector

(71) Applicant: Virginia Panel Corporation, Waynesboro, VA (US)

(72) Inventors: Adam Peter Shepard, McGaheysville, VA (US); Darryl M Ashby, Weyers Cave, VA (US)

(21) Appl. No.: 16/998,233

(22) Filed: Aug. 20, 2020

Related U.S. Application Data
(60) Provisional application No. 62/889,527, filed on Aug. 20, 2019.

(51) Int. Cl. H01R 13/518; H01R 13/622

(52) U.S. Cl. CPC H01R 13/518; H01R 13/622

(57) ABSTRACT

A docking connector having a first frame portion comprising a first elongated bar and a side extending perpendicular from each end of the first portion, wherein the first elongated bar has a plurality of spaced grooves perpendicular to the first bar, each groove being configured to receive an end of a module spaced along its length and a second frame portion comprising a second elongated bar, the second having a groove along its length for receiving a plurality of modules. The second frame portion is removably secured to the first frame portion with a screw at each end to form a frame having two pairs of opposing sides with the spaced grooves on the first bar and the groove on the second elongated bar facing an interior of the frame.

### CROSS-REFERENCE TO RELATED APPLICATIONS

The present application claims the benefit of the filing date of U.S. Provisional Patent Application Ser. No. 62/889,527 filed by the present inventors on Aug. 20, 2019.

The aforementioned provisional patent application is hereby incorporated by reference in its entirety.

### STATEMENT REGARDING FEDERALLY SPONSORED RESEARCH OR DEVELOPMENT

None.

### BACKGROUND OF THE INVENTION

### Field of the Invention

The present invention relates to a docking connector for holding modules for connector pins.

### Brief Description of the Related Art

A variety of electrical interface devices exist for housing modules that hold electrical and/or pneumatic contacts of various types. Examples of such interface devices are disclosed in U.S. Pat. Nos. 7,091,415, 7,297,014, 8,348,693, and 9,257,787. These various types of interface devices each have a receiver side and a test adapter side where the receiver side is connected to or mounted on test equipment and the test adapter side is connected to a unit under test. When the test adapter, known as an “ITA,” is mated to the receiver, a plurality of contact can be connected to each other in a stable and safe manner to minimize or eliminate damage to the contact during mating. The interface devices come in a wide variety of sizes that can hold small number of contacts or very large numbers of contacts.

The receiver and test adapter in an interface device typically each have a frame that holds a plurality of modules. The different types of interface devices often have modules of different dimensions such that modules from one interface type cannot be used in a different interface type. To overcome this problem, U.S. Pat. No. 8,351,218 discloses an interface device having multiple tiers such that modules of a first size can be mounted in the receiver or test adapter in one tier and modules of a second size can be mounted in the receiver or test adapter in a second tier. In this manner, modules of different sizes can be used simultaneously in the same interface device.

In small applications an engagement mechanism may not be necessary so a frame, referred to herein as a “docking connector,” is used to hold connector modules filled with connector pins to improve connection times. Exemplary prior docking connectors are shown in FIGS. 1A-1D and 2. Each of these prior docking connectors has two pairs of opposing sides to form a rectangular or square frame. As shown in the example in FIG. 1A, one pair of opposing sides, the top and bottom in FIG. 1A, has holes or other means for connecting a plurality of modules to the frame in a side-by-side manner. In other examples such as are shown in FIGS. 1B-1D, the frame includes intermediate members having holes or other means for connecting modules between the intermediate members and a side or between two intermediate members. Additionally, U.S. Published Patent Application No. 2018/0358735 discloses a configurable docking connector in which modules of differing sizes may be used.

### SUMMARY OF THE INVENTION

In a preferred embodiment, the present invention is a docking connector having a frame formed by a U-shaped member and a removable member, wherein the U-shaped member forms three sides of a rectangle, i.e., an elongated portion and two parallel sides extending from opposite ends of the elongated portion. Then each end of the elongated removable member is connected to an end of one of the parallel sides of the U-shaped member with a removable screw. Further, the elongated portion of the U-shaped member has a ridge facing the inside of the frame, wherein the ridge has a plurality of threaded holes for receiving screws to secure modules to the elongated member.

In another embodiment the present invention is a docking connector having a first frame portion comprising a first elongated bar and a side extending perpendicular from each end of the first portion, wherein the first elongated bar has a plurality of spaced grooves perpendicular to the first bar, each groove being configured to receive an end of a module spaced along its length and a second frame portion comprising a second elongated bar, the second having a groove along its length for receiving a plurality of modules. The second frame portion is removably secured to the first frame portion with a screw at each end to form a frame having two pairs of opposing sides with the spaced grooves on the first bar and the groove on the second elongated bar facing an interior of the frame.

In another embodiment, the present invention is a docking connector having a first frame portion and a second frame portion. The first frame portion has a first elongated bar having a first end, a second end, and a plurality of grooves perpendicular to and spaced along a length the first elongated bar, each the groove being configured to receive an end of a module spaced along the length of the first elongated bar; a first side bar extending from the first end of the first elongated bar perpendicular to the first elongated bar; and a second side bar extending from the second end of the first elongated bar perpendicular to the first elongated bar. The first and second side bars each have at an end away from the first elongated bar a first mounting member. The second frame portion has a second elongated bar having a first end and a second end and a second mounting member at each of first and second ends, the second elongated bar having a plurality of grooves perpendicular to and spaced along a length the second elongated bar, each groove being configured to receive an end of the module connected to the first elongated bar. The second frame portion is removably secured to the first frame portion by connecting the first mounting member of the first side bar to the second mounting member on the first end of the second elongated bar and connecting the first mounting member on the second side bar to the second mounting member on the second end of the second elongated bar to form a frame having two pairs of opposing sides with the spaced grooves on the first elongated bar and the grooves on the second elongated bar facing an interior of the frame. The first mounting members may be secured to the second mounting members, for example, with screws. The docking connector further may comprise a module having a first end in one of the grooves in the first elongated bar and a second end in the groove in the second elongated bar and a retaining bar secured to the first elongated bar to hold the module in the groove in the first elongated bar. The retaining bar is secured to the first elongated bar with screws. A plurality of contact pins may be mounted in the module.

Still other aspects, features, and advantages of the present invention are readily apparent from the following detailed description, simply by illustrating a preferable embodiments and implementations. The present invention is also capable of other and different embodiments and its several details can be modified in various obvious respects, all without departing from the spirit and scope of the present invention. Accordingly, the drawings and descriptions are to be regarded as illustrative in nature, and not as restrictive. Additional objects and advantages of the invention will be set forth in part in the description which follows and in part will be obvious from the description or may be learned by practice of the invention.

### BRIEF DESCRIPTION OF THE DRAWINGS

For a more complete understanding of the present invention and the advantages thereof, reference is now made to the following description and the accompanying drawings, in which:

FIGS. 1A-1D are perspective view of prior art docking connectors.

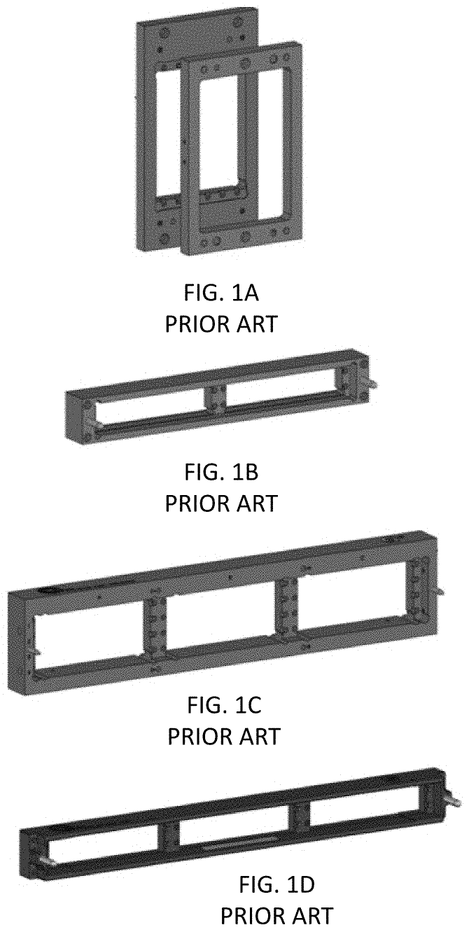

FIG. 2 is perspective assembly view of an interface system employing a secondary docking connector.

FIG. 3 is a side perspective view of PCB's in an enclosure or fixture having a secondary docking connector.

FIG. 4 is a perspective view of a quick exchange docking connector in accordance with a preferred embodiment of the present invention.

FIG. 5 is a side perspective view of a quick exchange docking connector in accordance with a preferred embodiment of the present invention with a module and PCB.

FIG. 6 is a partial close-up perspective view of a quick exchange docking connector in accordance with a preferred embodiment of the present invention with a module. The bottom bar of the docking connector is transparent to provide a view of the module in the docking connector.

FIG. 7 is a side view of a quick exchange docking connector in accordance with a preferred embodiment of the present invention with a module. The top bar of the docking connector is transparent to provide a view of the module in the docking connector.

### DETAILED DESCRIPTION OF THE PREFERRED EMBODIMENTS

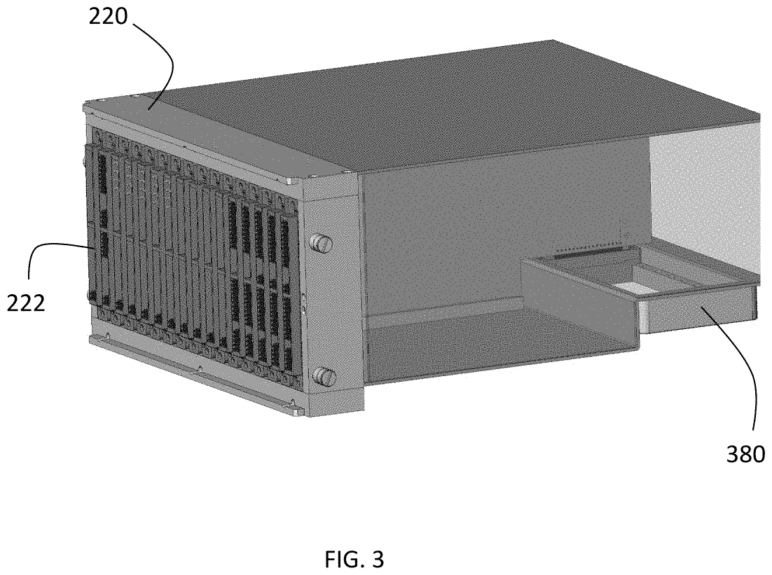

An application for a docking connector in accordance with the present invention may be referred to as a “secondary docking connector.” An example of such a system employing a “secondary docking connector” is shown in FIG. 3. The interface system 100 has a plurality of printed circuit boards (PCB's) 310 mounted in a fixture 300. The system has a standard interface comprising a receiver or receivers 210 mounted to test equipment (not shown) and a fixture or enclosure 300 having one or more interchangeable test adapters (ITA) 220 that each mate with the receiver 210. The test adapter 220 has a first plurality of modules 222 mounted in the test adapter 220, a plurality of PCB's 310 each having a first end connected to the first plurality of modules 222 and a secondary docking connector 380 having a second plurality of modules 350 connected to second ends of the plurality of PCB's. The modules 222 typically are each mounted to the test adapter frame with a screw at each end of the module. The enclosure or fixture 300 further has a cover 320 and supporting structure 330, 340.

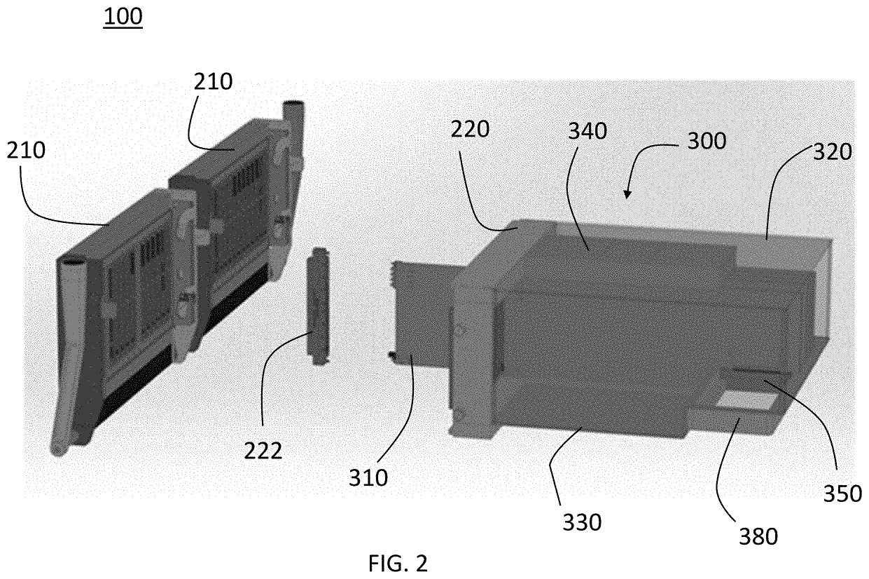

In FIG. 2, one of the PCB's 310 is shown in a position in which it appears to have been pulled out through the front of the text adapter 220. With a conventional docking connector, however, even if the screws mounting the module 222 are removed and the module is removed the PCB 310 cannot be removed through the face of the test adapter 220 because movement of the second plurality of modules 350 in that direction is blocked by the secondary docking connector 380. The present invention solves this shortcoming by providing a “quick exchange” docking connector that allows the bottom bar of the docking connector to be quickly removed to allow the PCB's to slide directly out of the face of the test adapter 220. The term “bottom bar” here is used to refer to the side of the docking connector frame that is closest to the test adapter 220. The opposing side of the docking connector that is furthest form the test adapter 220 is referred to herein at the “top bar.”

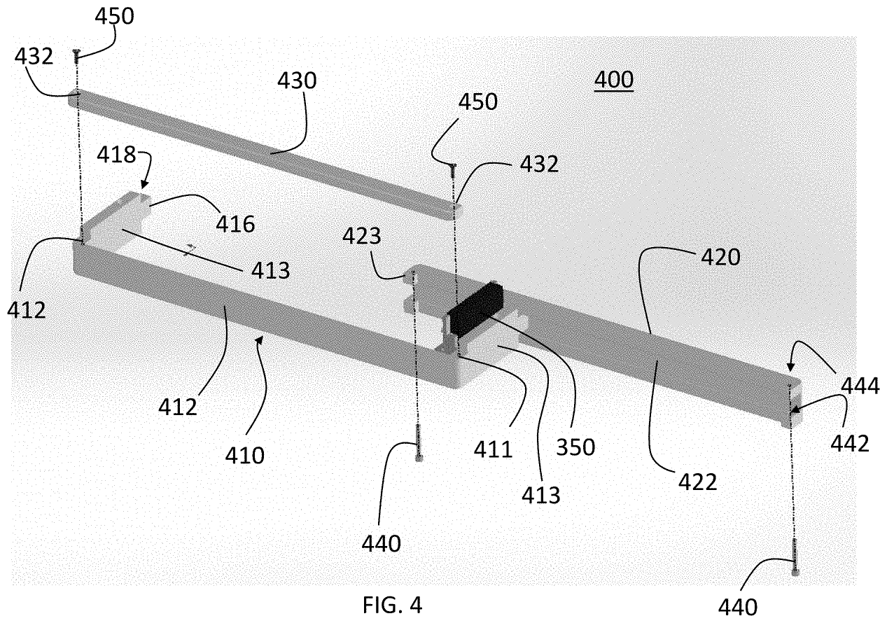

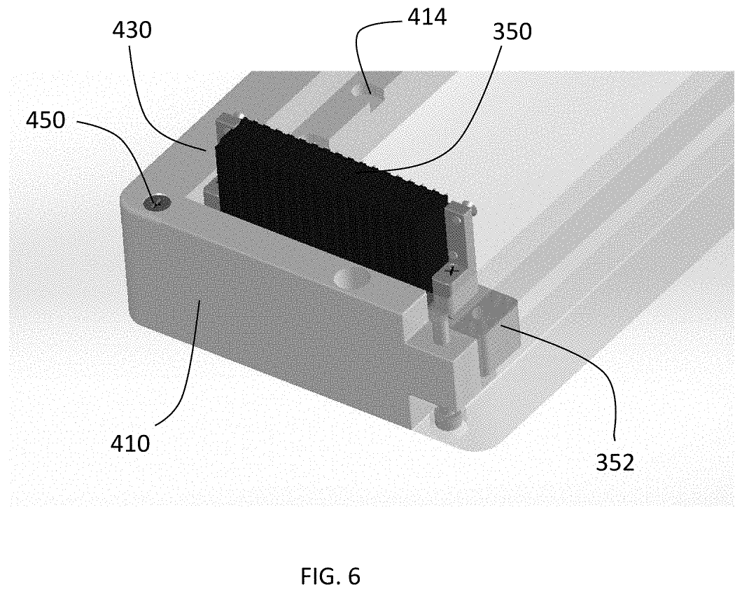

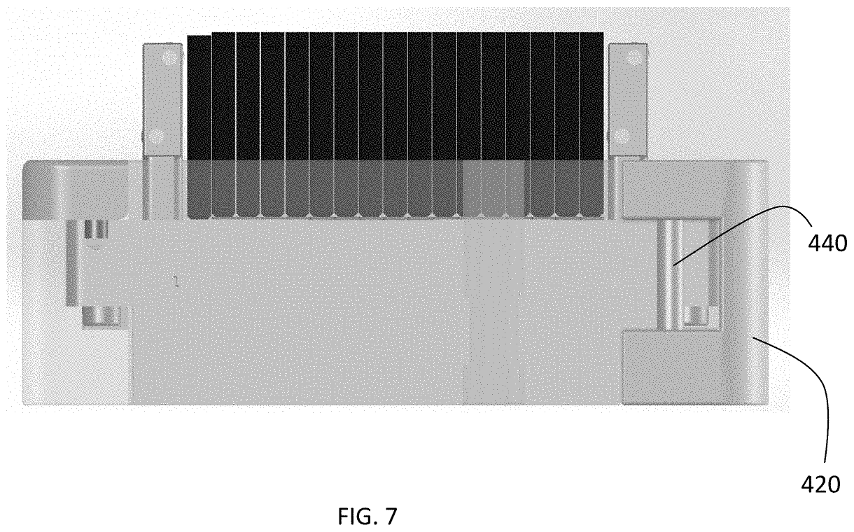

A quick exchange docking connector in accordance with a preferred embodiment of the present invention is described with reference to FIGS. 4-7. The quick exchange docking connector 400 has a top bar 412 having an elongated portion and a perpendicular side portion 413 extending from each end of the elongated portion. Each side portion 413 has a mounting member 416 adapted to engage with a mounting member on a second elongated bar 430. A removable bottom bar 420 is connected to the top bar 412 via screws 440 placed through thru-hole 442 in a mounting member 423 on the bottom bar 420 and thru-hole 418 in the top bar and secured in threaded holes 444. When connected the top bar and the bottom bar form a rectangular frame in which modules may be mounted. The elongated portion of the top bar 412 has on its side facing the interior of the docking connector frame has a plurality of horseshoe-shaped grooves 414 each for receiving an end of a module 350. The bottom bar 420 has a groove along is length facing the interior of the frame for receiving a second end of each module. Once modules are placed into the docking connector frame, a retaining bar 430 is secured to the top bar 412 to hold the modules 350 in place. The retaining bar 430 is secured to the top bar 412 via screws 450 placed through thru-holes 432 and into threaded holes 411. Contact pins (not shown) can be placed in the modules and patchcords (not shown) can be connected to the pins.

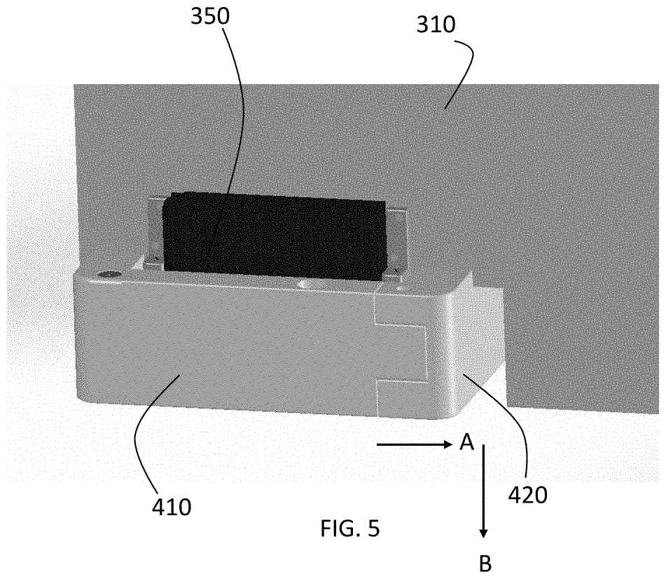

As shown in FIG. 5, to remove the PCB's through the front of the test adapter 220, the two screws 440 are removed from the docking connector thereby freeing the bottom bar 420 to be moved in Direction A away from the top bar and then in direction B to be removed altogether. If the screws securing the modules 222 o the test adapter 220 are removed (either before or after removing the bottom bar o the docking connector, once the bottom bar 420 is removed the PCB's can slide directly out of the front of the test adapter.

This quick exchange docking connector design provides for each removal of the PCB's from a fixture or enclosure for replacing, repairing, or otherwise servicing the PCB's.

The foregoing description of the preferred embodiment of the invention has been presented for purposes of illustration and description. It is not intended to be exhaustive or to limit the invention to the precise form disclosed, and modifications and variations are possible in light of the above teachings or may be acquired from practice of the invention. The embodiment was chosen and described in order to explain the principles of the invention and its practical application to enable one skilled in the art to utilize the invention in various embodiments as are suited to the particular use contemplated. It is intended that the scope of the invention be defined by the claims appended hereto, and their equivalents. The entirety of each of the aforementioned documents is incorporated by reference herein.

What is claimed is:

1. A docking connector comprising:
a first frame portion comprising:
a first elongated bar having a first end, a second end, and a plurality of grooves perpendicular to and spaced along a length said first elongated bar, each said groove being configured to receive an end of a module spaced along the length of the first elongated bar;
a first side bar extending from said first end of the first elongated bar perpendicular to said first elongated bar; and
a second side bar extending from said second end of the first elongated bar perpendicular to said first elongated bar
wherein said first and second side bars each have at an end away from said first elongated bar a first mounting member; and
a second frame portion comprising a second elongated bar having a first end and a second end and a second mounting member at each of first and second ends, said second elongated bar having a plurality of grooves perpendicular to and spaced along a length said second elongated bar, each groove being configured to receive an end of said module connected to said first elongated bar;
wherein said second frame portion is removably secured to said first frame portion by connecting said first mounting member of said first side bar to said second mounting member on said first end of said second elongated bar and connecting said first mounting member on said second side bar to said second mounting member on said second end of said second elongated bar to form a frame having two pairs of opposing sides with said spaced grooves on said first elongated bar and said grooves on said second elongated bar facing an interior of said frame.

2. A docking connector according to claim 1 wherein first mounting members are secured to said second mounting members with screws.

3. A docking connector according to claim 1 further comprising:
a module having a first end in one of said grooves in said first elongated bar and a second end in said groove in said second elongated bar; and
a retaining bar secured to said first elongated bar to hold said module in said groove in said first elongated bar.

4. A docking connector according to claim 3 wherein said retaining bar is secured to said first elongated bar with screws.

5. A docking connector according to claim 3 further comprising:
a plurality of contact pins mounted in said module.
